(19) United States
(12) Patent Application Publication
(10) Pub. No.: US 2003/0038329 A1
(43) Pub. Date: Feb. 27, 2003

(54) Photodetector and its operating modes

(75) Inventors: Sen-Shyong Fann, Hsinchu (TW); Huey-Liang Hwang, Hsinchu (TW); Yeu-Long Jiang, TaiChung (TW)

Correspondence Address: BRUCE H. TOXELL, SUITE 1404, 5205 LEESBURG PIKE, FALLS CHURCH, VA, 22041, US

(73) Assignee: CANDO CORPORATION

(21) Appl. No.: 10/128,509

(22) Filed: Apr. 24, 2002

(30) Foreign Application Priority Data
Aug. 24, 2001 (TW) 90120810

(51) Int. Cl. H01L 27/14

(52) U.S. Cl. 257/431

(57) ABSTRACT

A photodetector comprising a P-type, a N-type, an intrinsic layer, a first electrode corresponding to the P-type, a second electrode corresponding to the N-type, and a dielectric layer in such a way that the intrinsic layer is disposed between the P-type and the N-type for forming a diode and the dielectric layer is provided between the P-type and the first electrode (or between the N-type and the second electrode) for configuring a dielectric capacitor. By parallel connecting effective capacitor of reverse-biased diode and dielectric capacitor, the photodetector is capable of providing greatly increased capacitance. The operating modes involve charging the dielectric capacitor before subjecting the photodetector to photons for detecting signals.

### 1. FIELD OF THE INVENTION

The present invention relates to a photodetector and in particular relates to a photodetector having a dielectric layer as the capacitor on either end of the photo diode and its operating modes.

### 2. BACKGROUND OF THE INVENTION

Conventional films in X-ray radiography applications and detection have been used for years and would require a time-consuming development process before being displayed for inspection. A great deal of research efforts has thus been devoted to solid-state X-ray detecting devices in order to rid them out of the trouble of the development process. If an object subjected to X-ray is capable of getting detected by a solid-state detecting device and the object X-ray image can be displayed on a computer screen for inspection, it could save time, chemical solution and pollution commonly associated with film development. In addition to portability and the ability of getting quick images, such solid-state detecting devices could facilitate digitized images directly for storage, transmission, receipt and display in image systems. Those benefits offer solid-state detecting devices the potential of replacing conventional X-ray films in the future.

There are two kinds of solid-state detecting devices: direct X-ray detector and indirect X-ray detector. The direct detector is capable of detecting the X-ray photons without the help of a scintillator, whereas the indirect detector requires converting the X-ray to visible light before utilizing a visible light detector for actual detection.

FIG. 1 and FIG. 2 show structural perspective and its equivalent circuit diagram of a prior art photodetector application. Please refer to both figures. Prior art indirect X-ray photodetector is constructed on a substrate 100 in such a way that a photodiode 101 having a P-layer side, an intrinsic layer and a N-layer side is disposed on the substrate 100. The photodiode 101 comprises a P-type doped layer 102, a N-type doped layer 104, an intrinsic layer 106 being provided between the P-type doped layer 102 and the N-type doped layer 104, a first electrode 108 being electrically connected with P-type doped layer 102 and a second electrode 110 being electrically connected with the N-type doped layer 104. When a reverse bias is applied across the first electrode 108 and the second electrode 110, the intrinsic layer 106 between the P-type doped layer 102 and the N-type doped layer 104 would detect incident photons, form electron-hole pairs and generate photocurrent source I_{L}, while storing charges from the initial bias or generated by I_{L} in the P-type doped layer 102, the intrinsic layer 106 and the N-type doped layer 104 to form effective capacitance of reverse-biased diode C_{d}.

When relying alone on effective capacitance of reverse-biased diode C_{d} for storing charges, it would require a large effective capacitance of reverse-biased diode C_{d} and a very small leakage current associated with the leakage resistance of reverse-biased diode R_{dsh} to allow the photodiode to be of practical value. Therefore, prior art photodiodes must ensure elevation of the photovoltaic efficiency and effective capacitance of reverse-biased diode C_{d} while at the same time reducing the leakage current. These often-contradicting requirements would certainly render manufacturing processes to meet design specifications very difficult.

Since the charge capacity of effective capacitance of reverse-biased diode C_{d} is rather limited, prior art photodiodes frequently reach or exceed saturation during operation, thereby restricting its operating range. This easily explains why the yield rates are usually low for X-ray image array.

Moreover, prior art photodiodes often lack adequate data holding time that the integrated signals quickly fade, as a result of poor leakage current characteristics.

Therefore, the main object of the present invention is to unveil a photodector capable of greatly increasing the data holding time and simplifying the manufacturing processes while at the same time improving manufacturing yields.

In order to attain the above object, the present invention discloses a photodetector having a P-type doped layer, a N-type doped layer, an intrinsic layer, a first electrode corresponding to the P-type doped layer, a second electrode corresponding to the N-type doped layer, and a dielectric layer such that the intrinsic layer is disposed between the P-type doped layer and the N-type doped layer for configuring a diode and the dielectric layer is provided between the P-type and the first electrode (or between the N-type and the second electrode) for constituting a dielectric capacitor. By incorporating a virtual short between the first electrode and the second electrode so as to cause parallel connection between the effective capacitor (C_{d}) of reverse-biased diode and the dielectric capacitor (C_{d}) provided by the dielectric layer, the photodetector is able to provide greatly increased capacitance.

The structure of the present invention offers optimization of the charge storage capacity while simultaneously allowing desirable photodector performance design.

The operating modes of the photodetector in the present invention involve charging the dielectric capacitor before subjecting the photodetector to photons for measuring signals.

In a first operating mode of the present invention, a forward bias is applied to the dielectric layer for reaching a voltage level of between 2 volts and 10 volts, known as an initial voltage. As increasing number of charge accumulates in the dielectric capacitor, the voltage drop across the first electrode and the second electrode of the photodetector will reduce to zero volts for photo detection. The photodetector would then be operating under reversed bias provided by the initial voltage of between 2 volts and 10 volts. Note that the photocurrent generated by the operating photodetector would neutralize the charges stored in the dielectric layer. Following the photo detecting process, the same forward bias is applied on the dielectric layer again for reaching a voltage level of between 2 volts and 10 volts. It would then be possible to measure the neutralized charges and convert them to total detected photons and X-ray dosage.

In a second operating mode of the present invention, a reverse bias is applied across the first electrode and the second electrode of the photodetector for reaching a voltage level between 2 volts and 10 volts. The reverse bias starts charging the dielectric capacitor and most part of the applied voltage would remain across the dielectric layer as the charging process stabilizes. While maintaining stabilized reversed bias across the first electrode and the second electrode, the photodetector begins to detect the incident photons under no bias such that the photodetector acts as a photovoltaic cell for charging the dielectric layer. It would then be possible to obtain total detected photons and X-ray dosage by measuring the increased charge stored in the dielectric layer.

### SUMMARY OF THE INVENTION

Aimed at resolving the above disadvantages, the main object of the present invention is to provide a photodetector capable of providing greatly increased capacitance.

Another object of the present invention is to provide a photodetector capable of providing a wide operating range.

The third object of the present invention is to provide a photodetector capable of providing greatly increased signal effective holding time.

The fourth object of the present invention is to provide a photodetector capable of allowing independent optimization of the dielectric capacitor layer and the photodiode.

The fifth object of the present invention is to provide a photodetector capable of providing quick measurement reading, uncomplicated manufacturing processes and high yields.

The following Description and Designation of Drawings are provided in order to help understand the features and content of the present invention.

### BRIEF DESCRIPTION OF THE DRAWINGS

The accompanying drawings form a material part of this description, in which:

FIG. 1 is a structural perspective of a prior art photodetector.

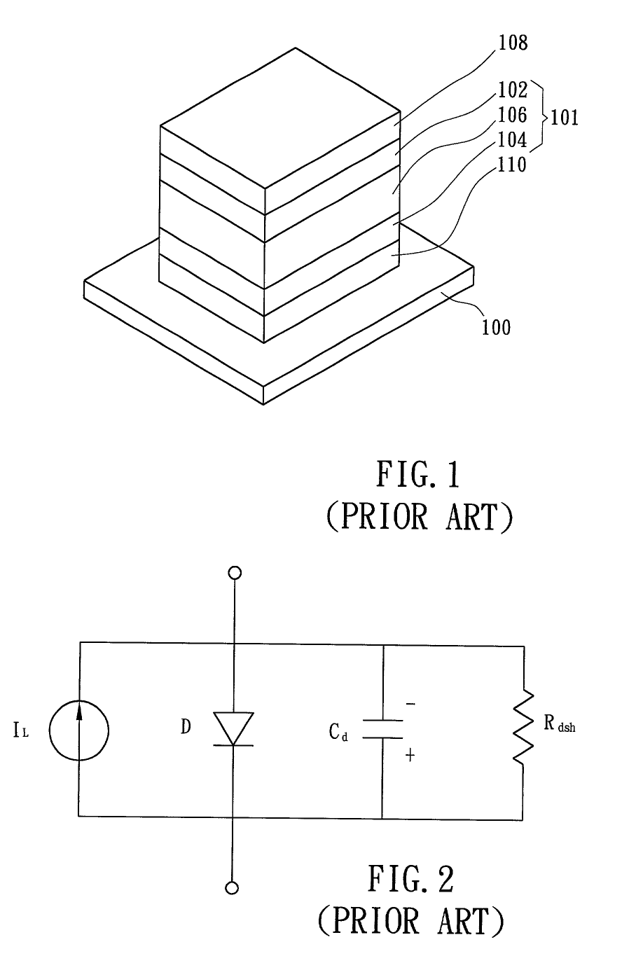

FIG. 2 is an equivalent circuit diagram of a prior art photodetector.

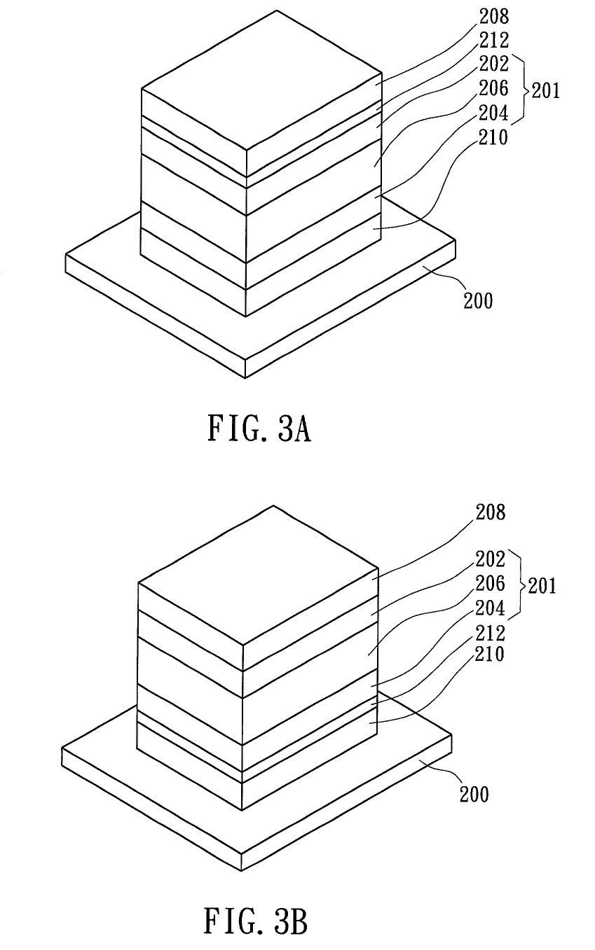

FIGS. 3A through 3D are structural perspectives of a photodetector in accordance with the first, the second, the third and the fourth embodiment of the present invention, respectively.

FIGS. 4A and 4B are equivalent circuit diagrams of a photodetector in accordance with the first embodiment of the present invention.

FIG. 5 is an equivalent circuit diagram of a photodetector with a signal-measuring circuit in accordance with the first embodiment of the present invention.

### DETAILED DESCRIPTION OF THE PREFERRED EMBODIMENT

In the following description, the present invention is described in connection with a specific and preferred embodiment. It will be understood that the present invention is not limited to these embodiments, but rather is to be construed as the spirit and scope defined by the appended claims.

In the present specification, the structure and process are described as comprising specific components and steps, respectively. It is within the contemplation of the present inventors that the structure and process can consist essentially of, or consist of, the disclosed components and steps, respectively.

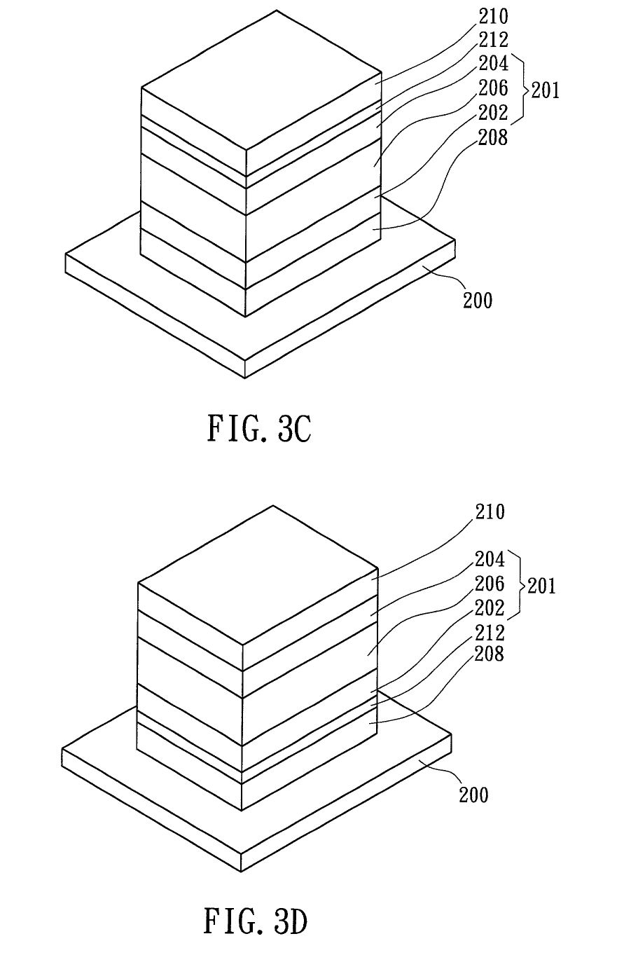

The present invention discloses a novel photodetector in order to resolve the aforementioned disadvantages associated with prior arts. Specific steps of the present invention are illustrated in the following paragraphs. FIGS. 3A through 3D show structural perspectives of a photodetector in accordance with the first, the second, the third, the fourth and the fifth embodiment of the present invention, respectively.

As shown in FIG. 3A, the photodetector in accordance with the first embodiment of the present invention is constructed on a substrate 200 in such a way that a second electrode 210, a N-type doped layer 204, an intrinsic layer 206, a P-type doped layer 202, a dielectric layer 212 and a first electrode 208 is provided in ascending order thereon. The N-type doped layer 204, the P-type doped layer 202, and the intrinsic layer 206, being disposed between the N-type doped layer 204 and the P-type doped layer 202, form an effective capacitance of reverse-biased diode while the P-type doped layer 202, the dielectric layer 212 and the first electrode 208 constitute a dielectric capacitance.

As shown in FIG. 3B, the photodetector in accordance with the second embodiment of the present invention is constructed on a substrate 200 in such a way that a second electrode 210, a dielectric layer 212, a N-type doped layer 204, an intrinsic layer 206, a P-type doped layer 202 and a first electrode 208 is provided in ascending order thereon. The N-type doped layer 204, the P-type doped layer 202, and the intrinsic layer 206, being disposed between the N-type doped layer 204 and the P-type doped layer 202, form an effective capacitance of reverse-biased diode while the N-type doped layer 204, the dielectric layer 212 and the second electrode 210 constitute a dielectric capacitance.

As shown in FIG. 3C, the photodetector in accordance with the third embodiment of the present invention is constructed on a substrate 200 in such a way that a first electrode 208, a P-type doped layer 202, an intrinsic layer 206, a N-type doped layer 204, a dielectric layer 212 and a second electrode 210 is provided in ascending order thereon. The N-type doped layer 204, the P-type doped layer 202, and the intrinsic layer 206, being disposed between the N-type doped layer 204 and the P-type doped layer 202, form an effective capacitance of reverse-biased diode while the N-type doped layer 204, the dielectric layer 212 and the second electrode 210 constitute a dielectric capacitance.

As shown in FIG. 3D, the photodetector in accordance with the third embodiment of the present invention is constructed on a substrate 200 in such a way that a first electrode 208, a dielectric layer 212, a P-type doped layer 202, an intrinsic layer 206, a N-type doped layer 204 and a second electrode 210, and is provided in ascending order thereon. The N-type doped layer 204, the P-type doped layer 202, and the intrinsic layer 206, being disposed between the N-type doped layer 204 and the P-type doped layer 202, form an effective capacitance of reverse-biased diode while the P-type doped layer 202, the dielectric layer 212 and the first electrode 208 constitute a dielectric capacitance.

The dielectric layer 212 in FIG. 3A through FIG. 3D is made of such materials as silicon oxide (SiOx), silicon nitride (SiNx), polymer or other dielectric materials.

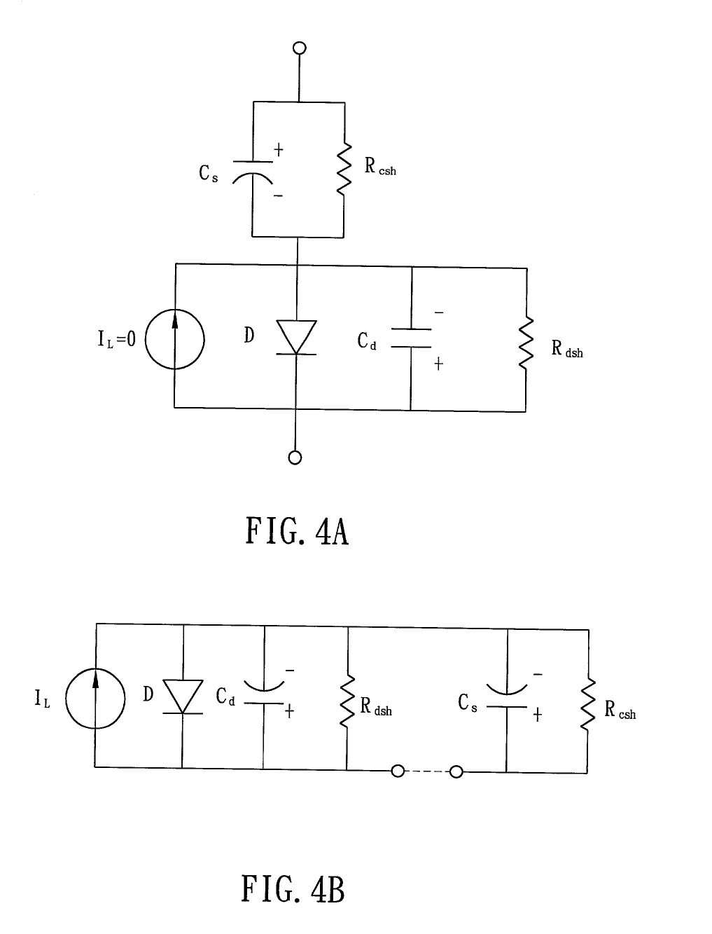

FIGS. 4A and 4B are equivalent circuit diagrams of a photodetector in accordance with the first embodiment of the present invention. There are two parts in the photodetector provided by the present invention, the first part having an effective capacitor of reverse-biased diode C_{d}, an ideal diode D, a leakage resistance of reverse-biased diode R_{dsh}, and a photocurrent source I_{L}, all in parallel, and the second part having a dielectric capacitor Cₛ and a leakage resistance of dielectric layer R_{csh} in parallel. Before the photodetector is exposed to photons, the value of photocurrent source I_{L} is zero.

As shown in FIG. 4B, virtual short between the first electrode and the second electrode, or equivalent, enables parallel connection between effective capacitor of reverse-biased diode C_{d} and dielectric capacitor Cₛ such that the photodetector is able to provide a greatly increased total capacitance C_{T}, equaling the sum of effective capacitance of reverse-biased diode C_{d} and dielectric capacitance Cₛ.

The intrinsic layer is employed in the present invention for photo detection while the dielectric capacitor Cₛ either accumulates the charge provided by photocurrent as a part of total capacitance C_{T} or stores the charge provided by photocurrent that neutralizes the charge stored in the dielectric layer. The two operating modes will be provided again in the following paragraphs. Involving uncomplicated manufacturing processes and comprising a electrode, a dielectric layer and either a P-type doped layer or a N-type doped layer, the dielectric capacitor Cₛ can easily provide capacitance some ten times the effective capacitance of reverse-biased diode C_{d}. With a total capacitance C_{T} equaling the sum of effective capacitance of reverse-biased diode C_{d} and dielectric capacitance of Cₛ, the photodetector in the present invention can thus provide a much wider operating range beyond prior art photodetectors.

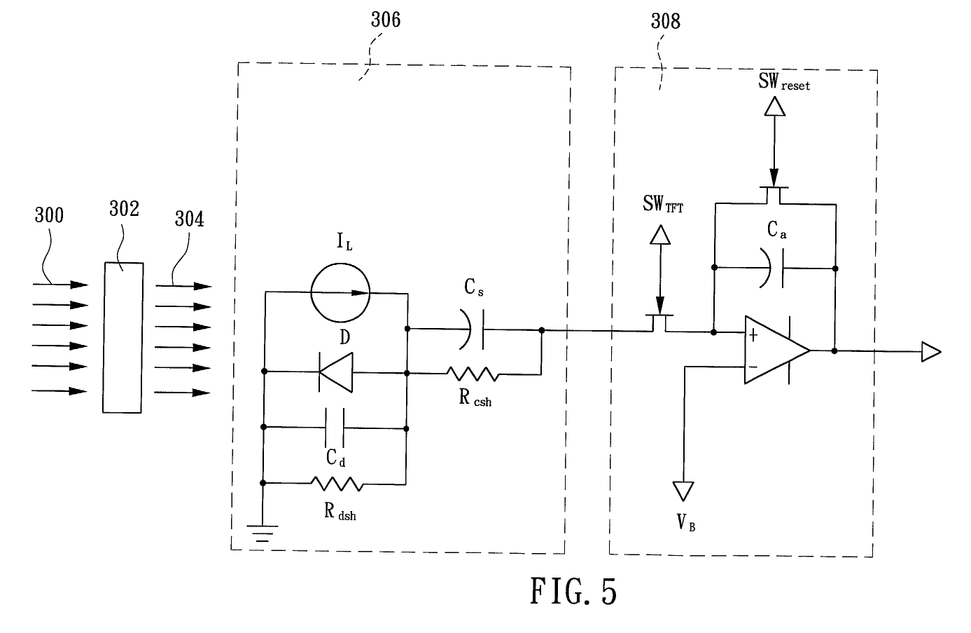

FIG. 5 shows an equivalent circuit diagram of a photodetector with a signal-measuring circuit in accordance with the first embodiment of the present invention. As shown in FIG. 5, when a X-ray 300 impinges upon a scintillator 302 and the scintillator 302 converts the X-ray to a visible light 304, the photodetector 306 in the present invention operates as an indirect X-ray detector by detecting the impinging visible light 304, thereby enabling a signal-measuring design 308 to display the X-ray dosage reading.

As shown in FIG. 5, with the photodetector 306 operating, the high total capacitance C_{T}, equaling the sum of effective capacitance of reverse-biased diode C_{d} and dielectric capacitance of Cₛ, help maintain an excellent signal holding time (τ=RC). Thus, the photodetector 306 in the present invention is able to correct prior art photodetector problems of not getting proper measurement as a result of insufficient capacitance. Moreover, the signal-measuring design 308 can cause the thin film transistor SW_{TFT} to turn off while awaiting the measurement reading, thereby increasing the signal effective holding time.

When the photodetector in the present invention operates as an indirect X-ray detector, the first operating mode comprises the following steps:

First, a forward bias is applied to the dielectric layer for reaching a voltage level between 2 volts and 10 volts.

The next step is reducing the voltage drop across the first electrode and the second electrode of the photodetector to zero volts for photo detection. With an initial voltage of between 2 volts and 10 volts remaining in the dielectric layer, the photodetector would then be operating under reverse-biased condition of between 2 volts and 10 volts. The photocurrent generated by the operating photodetector would neutralize a part of the charges stored in the dielectric layer.

Following the photo detecting process, a forward bias with the same voltage applied on the dielectric layer again for reaching a voltage level of between 2 volts and 10 volts. It would then be possible to measure the neutralized charges. Since the photocurrent intensity and charge collection time is proportional to the amount of the impinging photons, the measurement of the neutralized charge can be converted to total detected photons and X-ray dosage.

When the photodetector in the present invention operates as an indirect X-ray detector, the second operating mode comprises the following steps:

First, a reverse bias is applied across the first electrode and the second electrode of the photodetector for reaching a voltage level of between 2 volts and 10 volts. The reverse bias starts charging the dielectric layer and most applied voltage would remain across the dielectric layer as the charging process stabilizes.

While maintaining stabilized reverse bias across the first electrode and the second electrode, the photodetector begins to operate under no bias such that the photodetector acts as a photovoltaic cell for charging the dielectric layer while a net potential of charging loop raises the voltage of the photovoltaic cell.

It would finally be possible to obtain total detected photons and X-ray dosage by measuring the increased charge stored in the dielectric layer.

In light of the foregoing, the photodetector disclosed in the present invention possesses the following advantages:

1. By providing a dielectric capacitor layer between a P-type doped layer or a N-type and its corresponding electrode, the dielectric layer in the present invention is a passive device and requires uncomplicated manufacturing processes while being able to provide a dielectric capacitance of Cₛ some ten times the effective capacitance of reverse-biased diode C_{d} of prior art photodetectors.

2. By incorporating proper circuit design of paralleling the effective capacitor of reverse-biased diode C_{d} and the dielectric capacitor Cₛ, the photodetector in the present invention can provide a very high total dielectric capacitance C_{T} (C_{T}=C_{d}+Cₛ) for a much wider operating range than prior art photodetectors.

3. The device structure disclosed in the present invention allows independent optimization of the dielectric capacitor layer and the photodiode performance, whereas in prior art photodiode, it would require simultaneous consideration of charge storage capability and photodetecting sensitivity and noise level. Therefore, the photodetector in the present invention is able to offer such benefits as quick measurement reading, uncomplicated manufacturing processes and high yields.

While the invention has been described in terms of preferred embodiments, various alternatives and modifications can be devised by those skilled in the art without departing from the invention. Accordingly, the present invention is intended to embrace all such alternatives that fall within the scope of the claims.

What is claimed is:

1. A photodetector, comprising:
a diode having a first doped layer, an intrinsic layer, a second doped layer such that the intrinsic layer is disposed between the first doped layer and the second doped layer and the diode has a effective capacitance of reverse-biased diode under reversed bias;
a first electrode being electrically connected with the first doped layer;
a second electrode being electrically connected with the second doped layer; and
a dielectric layer being provided between the second electrode and the second doped layer such that the second electrode, the dielectric layer and the second doped layer to form a dielectric layer capacitor.

2. The photodetector as in claim 1 wherein the first doped layer is a N-type doped layer and the second doped layer is a P-type doped layer.

3. The photodetector as in claim 1 wherein the first doped layer is a P-type doped layer and the second doped layer is a N-type doped layer.

4. The photodetector as in claim 1 wherein the dielectric layer is made of materials such as silicon oxide (SiOx), silicon nitride (SiNx), polymer.

5. The photodetector as in claim 1, wherein:
prior to a photo-detecting operation of the photodetector, apply a first forward bias across the first electrode and the second electrode for charging the dielectric layer capacitor to a first voltage;
during the photo-detecting operation of the photodetector, convert the first forward bias for the diode to expose to photons to reverse bias for the diode so as to neutralize a portion of the charge in the dielectric layer capacitor by the reverse-biased photodiode; and
following the photo-detecting operation of the photodetector, apply a second forward bias across the first electrode and the second electrode for charging the dielectric layer capacitance to the first voltage.

6. The photodetector as in claim 1, wherein:
prior to a photo-detecting operation of the photodetector, apply a reversed bias across the first electrode and the second electrode for charging the dielectric layer capacitor and an effective capacitor of reverse-biased diode; and
during the photo-detecting operation of the photodetector, maintain the reversed bias while the diode is exposed to photons, the diode turns to be a phovoltaic cell and continues to charge the dielectric layer capacitance.

7. A photodetector, comprising:
a diode having a first doped layer, an intrinsic layer, a second doped layer such that the intrinsic layer is disposed between the first doped layer and the second doped layer and the diode has an effective capacitor of reverse-biased diode under reversed bias;
a dielectric layer being provided on the first doped layer of the diode;
a first conductive layer being disposed on the dielectric layer such that the electrode of the first conductive layer, the dielectric layer and the first doped layer form a dielectric layer capacior; and
a second conductive layer being disposed on the second doped layer.

8. The photodetector as in claim 7 wherein the first doped layer is a N-type doped layer and the second doped layer is a P-type doped layer.

9. The photodetector as in claim 7 wherein the first doped layer is a P-type doped layer and the second doped layer is a N-type doped layer.

10. The photodetector as in claim 7 wherein the dielectric layer is made of materials such as silicon oxide (SiOx), silicon nitride (SiNx), polymer.

11. The photodetector as in claim 7, wherein:
prior to a photo-detecting operation of the photodetector, apply a first forward bias across the first conductive layer and the second conductive layer for charging the dielectric layer capacitance to a first voltage;
during the photo-detecting operation of the photodetector, convert the first forward bias for the diode to expose to photons to reverse bias for the diode so as to neutralize a portion of the charge in the dielectric layer capacitor by the reverse-biased photodiode; and
following the photo-detecting operation of the photodetector, apply a second forward bias across the first electrode and the second electrode for charging the dielectric layer capacitor to the first voltage.

12. The photodetector as in claim 7, wherein:
prior to a photo-detecting operation of the photodetector, apply a reversed bias across the first conductive layer and the second conductive layer for charging the dielectric layer capacitor and an effective capacitance of reverse-biased diode; and
during the photo-detecting operation of the photodetector, maintain the reversed bias while the diode is exposed to photons, the diode turns to be a phovoltaic cell and continues to charge the dielectric layer capacitance.
